(19) United States
(12) Patent Application Publication
(10) Pub. No.: US 2026/0221799 A1
(43) Pub. Date: Jul. 30, 2026

(54) UNDERVOLTAGE PROTECTION CIRCUIT AND MOTOR CONTROL CIRCUIT

(71) Applicant: LG INNOTEK CO., LTD., Seoul (KR)

(72) Inventor: Kun Min LEE, Seoul (KR)

(21) Appl. No.: 19/146,684

(22) PCT Filed: Dec. 27, 2023
(86) PCT No.: PCT/KR2023/021666

§ 371 Date: Jul. 9, 2025

(30) Foreign Application Priority Data
Jan. 9, 2023 (KR) 10-2023-0002675
Jan. 11, 2023 (KR) 10-2023-0003885

(51) Int. Cl. H02J 9/06; G01R 19/165; G01R 31/3835; H02P 3/06

(52) U.S. Cl. CPC H02J 9/061; G01R 19/16533; G01R 31/3835; H02P 3/06

(57) ABSTRACT

An embodiment discloses an undervoltage protection circuit including a comparison unit which compares a battery voltage and a reference voltage, a charging unit including a capacitor, and a switching unit which allows any one of a voltage of the charging unit and the battery voltage to be supplied to a power source of a communication unit according to an output of the comparison unit.

### TECHNICAL FIELD

An embodiment relates to an undervoltage protection circuit and a motor control circuit.

### BACKGROUND ART

Controller area network (CAN) communication is a communication standard designed such that microcontrollers or devices communicate with each other without host computers in vehicles. A message-based protocol is used in CAN communication, and CAN communication is frequently used in industrial automation apparatuses or medical apparatuses in addition to vehicles. CAN communication has communication advantages in terms of cost, usefulness, and robustness.

Conventionally, there is a problem of occurrence of an undervoltage and a problem with connection of the CAN communication due to voltage drop which may occur when a vehicle starts. A CAN communication integrated circuit (IC) is generally operated by receiving a battery voltage, and in conventional designs, a phenomenon in which CAN communication is impossible due to lack of a minimum time at a reference voltage for operating the IC may occur in an undervoltage state occurring when a vehicle starts. A condenser with a large capacity is installed on a battery voltage line in order to prevent the phenomenon so that the minimum time is secured, but there is a problem that such a method cannot be applied to a structure of a current product. The conventional CAN communication IC directly receives a battery input voltage and determines whether the battery input voltage is within an on/off range based on a reference voltage, and a CAN communication impossible section may be generated in a low temperature due to voltage drop of a diode. A method of maintaining CAN communication in the CAN communication impossible section due to such an undervoltage is required.

In addition, there is a problem of occurrence of an undervoltage and a problem with driving of a motor due to voltage drop of a battery which may occur when a vehicle starts. Generally, a motor is driven by receiving a battery voltage, and in the conventional design, driving of a motor can be stopped using a voltage of a DC link capacitor in an undervoltage state occurring due to a voltage of a vehicle battery input to a control unit caused by internal/external problems of the vehicle when the vehicle starts. In this case, a problem that the stopping of the driving of the vehicle is delayed may occur due to recognition of a dropped voltage which has been applied to an inductor, a capacitor, etc. Accordingly, design of a circuit capable of preventing occurrence of delayed stop in a case in which driving of a motor is stopped when an undervoltage of a battery in a vehicle occurs is required.

### CONTENT OF INVENTION

### Technical Problem

An embodiment is directed to providing an undervoltage protection circuit capable of securing controller area network (CAN) communication in a CAN communication impossible section due to an undervoltage when a vehicle starts.

In addition, an embodiment is directed to providing an undervoltage protection circuit capable of reducing a discharge rate in a CAN communication impossible section due to an undervoltage when a vehicle starts.

In addition, an embodiment is directed to providing an undervoltage protection method capable of reducing a discharge rate in a CAN communication impossible section due to an undervoltage when a vehicle starts.

An embodiment is directed to providing a motor control circuit capable of reducing a time required to stop driving of a motor when an undervoltage occurs.

An embodiment is directed to providing a motor control circuit with improved response for operation stop of a motor.

Problems to be solved by embodiments are not limited thereto and include objectives or effects that may be identified through solutions to the problems or embodiments which will be described below.

### Technical Solution

An undervoltage protection circuit according to the embodiment includes a comparison unit which compares a battery voltage and a reference voltage, a charging unit including a capacitor, and a switching unit which allows any one of a voltage of the charging unit and the battery voltage to be supplied to a power source of a communication unit according to an output of the comparison unit.

The switching unit of the undervoltage protection circuit according to the embodiment may allow the battery voltage to be supplied to the power source of the communication unit when the battery voltage is higher than the reference voltage.

The switching unit of the undervoltage protection circuit according to the embodiment may allow a voltage of the capacitor in the charging unit to be supplied to the power source of the communication unit when the battery voltage is lower than the reference voltage.

The undervoltage protection circuit according to the embodiment may include a resistor disposed between the charging unit and the switching unit.

The reference voltage of the undervoltage protection circuit according to the embodiment may range from 3.3 V to 3.7 V.

The comparison unit of the undervoltage protection circuit according to the embodiment may transmit a signal for turning a power source of the switching unit off when the battery voltage is higher than the reference voltage.

The comparison unit of the undervoltage protection circuit according to the embodiment may transmit a signal for turning a power source of the switching unit on when the battery voltage is lower than the reference voltage.

The switching unit of the undervoltage protection circuit according to the embodiment may allow a current supplied by the charging unit to flow to a power source of the communication unit when the power source of the switching unit is turned on.

The switching unit of the undervoltage protection circuit according to the embodiment may be disposed between and electrically connected to the comparison unit, the charging unit, and the power source of the communication unit.

The undervoltage protection circuit according to the embodiment includes a voltage supply unit which generates the reference voltage.

A motor control circuit according to the embodiment includes a comparison unit which compares magnitudes of a plurality of voltages, a gate unit which adjusts power to control a motor, and a capacitor unit which is charged with charges and supplies a current to a bridge circuit unit, wherein the comparison unit transmits a signal according to a result of comparing the magnitudes of the plurality of voltages to the gate unit, the gate unit adjusts power according to the result of comparing the magnitudes of the plurality of voltages, and an input node at which the comparison unit receives the voltages is disposed in front of a supply node at which the capacitor unit receives the voltages.

The plurality of voltages of the motor control circuit according to the embodiment may include a first voltage and a second voltage, the first voltage may be an input voltage, and the second voltage may be a comparison voltage.

The signal of the motor control circuit according to the embodiment may include a first signal and a second signal, the first signal may be a signal for allowing a current to flow, and the second signal may be a signal for blocking the current.

The comparison unit of the motor control circuit according to the embodiment may transmit the first signal to the gate unit when the first voltage is higher than the second voltage and transmit the second signal to the gate unit when the first voltage is lower than the second voltage.

The gate unit of the motor control circuit according to the embodiment may transmit a signal for turning a power source on to drive a motor when the gate unit receives the first signal and transmit a signal for turning a power source off to stop operation of the motor when the gate unit receives the second signal.

The capacitor unit of the motor control circuit according to the embodiment may be disposed between the comparison unit and gate unit and the motor.

The motor control circuit according to the embodiment may include a sub-gate unit which allows a current to flow when each of all input signals is the first signal, and the sub-gate unit may be disposed between the comparison unit and the gate.

The sub-gate unit of the motor control circuit according to the embodiment may transmit the first signal to the gate unit when all input signals are the first signals and block a current when any one signal of the input signals is the second signal.

The motor control circuit according to the embodiment may include a power management unit which converts and manage a current and distributes the current to the motor, and the power management unit may be connected to the sub-gate unit.

The motor control circuit according to the embodiment may include a comparison voltage supply unit which supplies the second voltage, and the second voltage may be 6 V.

The motor control circuit according to the embodiment may include a coil unit which generates a voltage according to a change in current, and the coil unit may be disposed between the input node and the capacitor unit.

### Advantageous Effects

According to an embodiment, an undervoltage protection circuit capable of securing controller area network (CAN) communication in a CAN communication impossible section due to an undervoltage when a vehicle starts can be implemented.

In addition, an undervoltage protection circuit capable of reducing a discharge rate in a CAN communication impossible section due to an undervoltage when a vehicle starts can be implemented.

In addition, a method capable of reducing a discharge rate in a CAN communication impossible section due to an undervoltage when a vehicle starts can be provided.

According to an embodiment, a motor control circuit capable of reducing a time required to stop driving of a motor when an undervoltage occurs can be provided.

In addition, a motor control circuit with improved response for operation stop of a motor can be provided.

Various useful advantages and effects of the present invention are not limited to the above-described content and may be more easily understood from description of specific embodiments of the present invention.

### DESCRIPTION OF DRAWINGS

FIG. 1 is a circuit diagram illustrating a conventional communication unit.

FIG. 2 is a block diagram illustrating an undervoltage protection circuit according to an embodiment.

FIG. 3 is a circuit diagram illustrating the undervoltage protection circuit according to the embodiment.

FIG. 4 is a circuit diagram illustrating a charging unit according to the embodiment.

FIG. 5 is a flowchart illustrating an undervoltage protection method of the undervoltage protection circuit according to the embodiment.

FIG. 6 is a graph showing a change in voltage according to the undervoltage protection circuit according to the embodiment.

FIG. 7 is a circuit diagram illustrating a conventional motor control circuit.

FIG. 8 is a block diagram illustrating a motor control circuit according to the embodiment.

FIG. 9 is a circuit diagram illustrating the motor control circuit according to the embodiment.

FIG. 10 is a circuit diagram illustrating a motor control circuit according to another embodiment.

FIG. 11 is a flowchart illustrating a method of controlling a motor of the motor control circuit according to the embodiment.

FIG. 12 is a graph showing a change in voltage according to the conventional motor control circuit.

FIG. 13 is a graph showing a change in voltage according to the motor control circuit according to the embodiment.

### MODES OF THE INVENTION

Hereinafter, exemplary embodiments of the present invention will be described in detail with reference to the accompanying drawings.

However, the technical spirit of the present invention is not limited to the few embodiments which will be described and may be implemented in a variety of different forms, and one or more components of the embodiments may be selectively combined, substituted, and used within the range of the technical spirit of the present invention.

In addition, unless clearly and specifically defined otherwise by the context, all terms (including technical and scientific terms) used herein can be interpreted as having meanings customarily understood by those skilled in the art, and the meanings of generally used terms, such as those defined in commonly used dictionaries, will be interpreted in consideration of contextual meanings of the related art.

In addition, the terms used in the embodiments of the present invention are considered in a descriptive sense only and not to limit the present invention.

In the present specification, unless specifically indicated otherwise by the context, singular forms include plural forms, and in a case in which “at least one (or one or more) among A, B, and C” is described, this may include at least one combination among all possible combinations of A, B, and C.

In addition, in descriptions of components of the present invention, terms such as “first,” “second,” “A,” “B,” “(a),” and “(b)” may be used.

The terms are only to distinguish one component from another component, and the essence, order, and the like of the components are not limited by the terms.

In addition, it should be understood that, when a first component is referred to as being “connected,” “coupled,” or “linked” to a second component, such a description may include both a case in which the first component is directly connected, coupled, or linked to the second component, and a case in which the first component is connected, coupled, or linked to the second component with a third component disposed therebetween.

In addition, when a first component is described as being formed or disposed “on (above)” or “under (below)” a second component, such a description includes both a case in which the two components are formed or disposed in direct contact with each other and a case in which one or more other components are interposed between the two components. In addition, when the first component is described as being formed “on (above) or under (below)” the second component, such a description may include a case in which the first component is formed at an upper side or a lower side with respect to the second component.

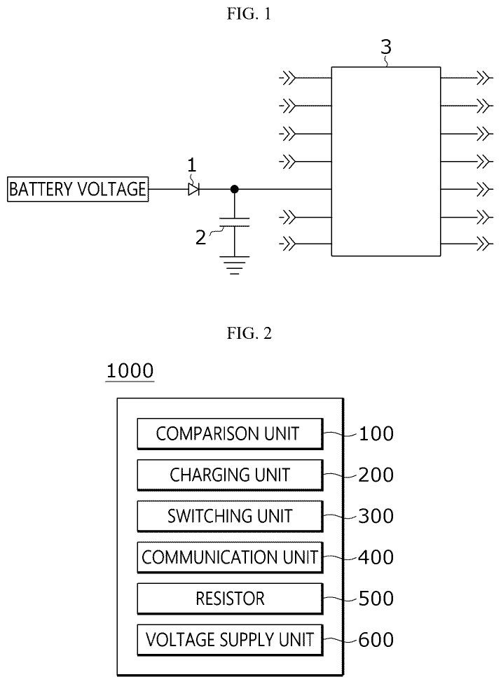

FIG. 1 is a circuit diagram illustrating a conventional communication unit.

Referring to FIG. 1, the conventional communication unit may receive a battery voltage through a circuit including a diode 1 and a capacitor 2.

In the conventional communication unit, the battery voltage may be transmitted to the communication unit 3 through the diode 1. Since a separate undervoltage protection circuit is not connected to the conventional communication unit, when an undervoltage occurs, a problem that communication of the communication unit 3 is impossible may occur in a corresponding undervoltage section.

FIG. 2 is a block diagram illustrating an undervoltage protection circuit according to an embodiment.

Referring to FIG. 2, an undervoltage protection circuit 1000 according to the embodiment may include a comparison unit 100, a charging unit 200, a switching unit 300, a communication unit 400, a resistor 500, and a voltage supply unit 600.

FIG. 3 is a circuit diagram illustrating the undervoltage protection circuit according to the embodiment.

Referring to FIGS. 2 and 3, the undervoltage protection circuit 1000 according to the embodiment may include the comparison unit 100 which compares a battery voltage and a reference voltage, the charging unit 200 including a capacitor, and the switching unit 300 which allows any one of a voltage of the charging unit 200 and the battery voltage to be supplied to the power source of the communication unit according to an output of the comparison unit 100.

The comparison unit 100 of the undervoltage protection circuit 1000 according to the embodiment may compare the battery voltage and the reference voltage.

The comparison unit 100 may be connected to a plurality of lines. The comparison unit 100 may be connected to the plurality of lines and may receive voltages of the plurality of lines. The comparison unit 100 may be connected to two lines and may compare magnitudes of two voltages. The comparison unit 100 may receive two voltages through positive and negative terminals. The comparison unit 100 may compare the magnitudes of voltages input to the positive and negative terminals and generate a first signal or second signal according to a result of the comparison. When a voltage input to the positive terminal is higher, the comparison unit 100 may generate the first signal. When a voltage input to the negative terminal is higher, the comparison unit 100 may generate the second signal. The voltage input to the positive terminal of the comparison unit 100 may be the reference voltage. The voltage input to the negative terminal of the comparison unit 100 may be the battery voltage. The comparison unit 100 may compare a magnitude of the battery voltage and a magnitude of the reference voltage. The comparison unit 100 may be a comparator.

The comparison unit 100 according to the embodiment may transmit a signal for turning a power source of the switching unit 300 off when the battery voltage is higher than the reference voltage.

The comparison unit 100 according to the embodiment may transmit a signal for turning the power source of the switching unit 300 on when the battery voltage is lower than the reference voltage.

The comparison unit 100 may include a first signal voltage supply unit 110 and a second signal voltage supply unit 120. When the comparison unit 100 generates the first signal, the comparison unit 100 may transmit a voltage of the first signal voltage supply unit 110 to the switching unit 300. When the comparison unit 100 generates the second signal, the comparison unit 100 may transmit a voltage of the second signal voltage supply unit 120 to the switching unit 300.

The first signal voltage supply unit 110 may have a predetermined voltage. When the voltage of the first signal voltage supply unit 110 is transmitted to the switching unit 130, the switching unit 130 may turn the power source on.

A magnitude of the voltage of the second signal voltage supply unit 120 may be zero. When the comparison unit 100 generates the second signal, a magnitude of the voltage of the switching unit 130 may be zero. When the magnitude of the voltage of the switching unit 130 is zero, the power source of the switching unit 130 may be turned off. In this case, when the magnitude of the voltage input to the negative terminal is greater, the comparison unit 100 allows the voltage input to the negative terminal to be supplied and transmitted to the power source of the communication unit.

The battery voltage may be a voltage input to the communication unit. The battery voltage may be input to the comparison unit 100. Generally, a constant magnitude of the battery voltage may be maintained. The magnitude of the battery voltage may decrease when a vehicle starts. For example, the magnitude of the battery voltage may generally be 14 V, and when the vehicle starts, the magnitude of the battery voltage may decrease to 3.5 V. When the battery voltage decreases, a problem that communication is impossible because the voltage input to a power source of the communication unit is low may occur.

The reference voltage may be a voltage generated for comparison with the magnitude of the battery voltage. The reference voltage may be a voltage which is input to the comparison unit 100 with the battery voltage and is a reference for determining whether the battery voltage is an undervoltage. For example, the reference voltage may be 3.5 V. A battery voltage higher than the reference voltage may correspond to a normal state and a battery voltage lower than the reference voltage may correspond to an undervoltage state. The reference voltage may be generated by the voltage supply unit 600. The reference voltage according to the embodiment may range from 3.3 V to 3.7 V.

The undervoltage protection circuit 1000 according to the embodiment may include the charging unit 200.

The charging unit 200 may be charged with charges and may generate and supply a voltage. The charging unit 200 may be connected to the switching unit 300. The charging unit 200 may supply or not supply a voltage to the power source of the communication unit 400 according to whether the power source of the switching unit 300 is turned on or off. The charging unit 200 may include a capacitor (condenser) and a ground unit.

When the battery voltage is lower than the reference voltage, the charging unit 200 may supply the voltage to the communication unit 400. When the battery voltage is lower than the reference voltage, the charging unit 200 may supply the voltage to the communication unit 400 to solve the problem that the communication is impossible in the undervoltage state. When the switching unit 300 transmits a voltage of the first signal voltage supply unit 110, and the power source of the switching unit 300 is turned on, the charging unit 200 may supply the voltage to the power source of the communication unit 400 through the switching unit 300. When the undervoltage occurs, the charging unit 200 may supply a voltage to the communication unit 400 instead of the battery voltage to supplement a voltage supplied to the communication unit 400. When the voltage supplied to the communication unit 400 is supplemented in an undervoltage state, since a discharge time of the voltage of the communication unit 400 may increase, a voltage higher than or equal to a limiting voltage at which communication is impossible may be maintained.

The undervoltage protection circuit 1000 according to the embodiment may include the switching unit 300.

The switching unit 300 may connect any one of the charging unit 200 and the battery voltage as the power source of the communication unit 400 according to an output of the comparison unit 100. The switching unit 300 may turn the power source on or off according to a voltage input thereto. The switching unit 300 is electrically connected to the comparison unit 100, the charging unit 200, and the communication unit 400. The switching unit 300 may turn the power source on or off according to a voltage output by the comparison unit 100. For example, the switching unit 300 may be a metal-oxide-semiconductor field effect transistor (MOSFET). The switching unit 300 may be the MOSFET.

When the power source is turned on, the switching unit 300 according to the embodiment may allow a current supplied by the charging unit 200 to flow to the power source of the communication unit 400.

When the battery voltage is lower than the reference voltage, and the comparison unit 100 transmits the voltage of the first signal voltage supply unit 110, the switching unit 300 may turn the power source on. When the power source of the switching unit 300 is turned on, the switching unit 300 may connect and supply a charge voltage of the charging unit 200 to the power source of the communication unit 400.

When the comparison unit 100 transmits the voltage of the second signal voltage supply unit 120 because the battery voltage is lower than the reference voltage, the switching unit 300 may turn a power source off. When the power source of the switching unit 300 is turned off, the switching unit 300 may connect and supply the battery voltage to the power source of the communication unit 400.

When the battery voltage is higher than the reference voltage, the switching unit 300 according to the embodiment may connect the battery voltage as the power of the communication unit 400. The switching unit 300 may receive the battery voltage through a line different from a line of the voltage of the second signal voltage supply unit 120. When the battery voltage is higher than the reference voltage, the switching unit 300 may receive the voltage of the second signal voltage supply unit 120 and turn a switch off, and in this case, the switching unit 300 may receive the battery voltage and connect the battery voltage to the power source of the communication unit 400.

When the battery voltage is lower than the reference voltage, the switching unit 300 according to the embodiment allows a voltage of the capacitor in the charging unit 200 to be supplied to the power source of the communication unit 400. The switching unit 300 allows the voltage charged to the capacitor of the charging unit 200 to be supplied to the power source of the communication unit 400. When the battery voltage is lower than the reference voltage, the switching unit 300 may receive the voltage of the first signal voltage supply unit 110 and turn a switch on, and in this case, the switching unit 300 may receive the voltage of the capacitor of the charging unit 200 and supply the voltage to the power source of the communication unit 400.

The switching unit 300 according to the embodiment may be disposed between and electrically connected to the comparison unit 100, the charging unit 200, and the power source of the communication unit 400.

As the switching unit 300 is disposed between and connected to the comparison unit 100, the charging unit 200, and the power source of the communication unit 400, the switching unit 300 may receive a voltage of the comparison unit 100 and transmit the voltage to the communication unit 400 or receive a voltage of the charging unit 200 and transmit the voltage to the communication unit 400.

The undervoltage protection circuit 1000 according to the embodiment may include the communication unit 400.

The communication unit 400 may be a controller area network (CAN) communication integrated circuit (IC). The communication unit 400 may receive the battery voltage and perform communication. When the communication unit 400 does not receive a voltage higher than the limiting voltage, the communication may be impossible. When an undervoltage state occurs and thus the battery voltage becomes lower than the limiting voltage, a magnitude of a voltage supplied to the communication unit 400 may be suddenly reduced, and thus the communication is impossible.

The communication unit 400 may receive the battery voltage through the switching unit 300 or receive the voltage of the charging unit 200. Since a battery voltage higher than the reference voltage corresponds to a normal state, the communication unit 400 may receive the battery voltage and operate normally, and since a battery voltage lower than the reference voltage corresponds to the undervoltage state, the communication unit 400 may receive the voltage of the charging unit 200 to supplement a voltage. When the voltage of the charging unit 200 is supplemented, a reduction rate of the voltage may be decreased to delay a time at which the voltage reaches the limiting voltage. Accordingly, the communication is prevented from being stopped until a time at which the magnitude of the battery voltage is restored.

The undervoltage protection circuit 1000 according to the embodiment may include the resistor 500 disposed between the charging unit 200 and the switching unit 300.

The undervoltage protection circuit 1000 may include the resistor 500 to distribute a voltage or limit an intensity of a current.

The reference voltage according to the embodiment may range from 3.3 V to 3.7 V.

The undervoltage protection circuit 1000 according to the embodiment may include the voltage supply unit 600 which generates the reference voltage.

The voltage supply unit 600 may generate the reference voltage. The voltage supply unit 600 may be electrically connected to the comparison unit 100 and may transmit the reference voltage to the comparison unit 100. The reference voltage may be generated and compared with the battery voltage to determine whether the battery voltage is the undervoltage.

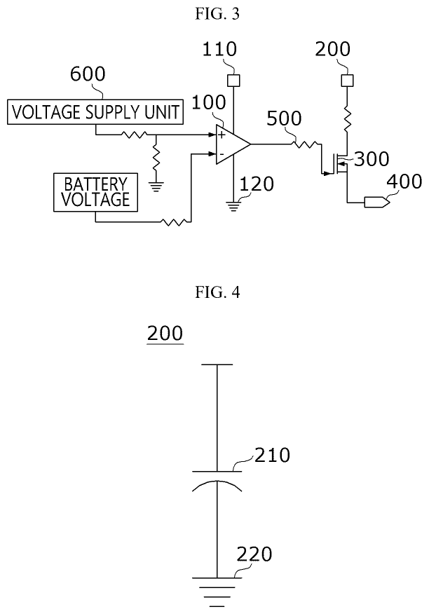

FIG. 4 is a circuit diagram illustrating the charging unit according to the embodiment.

Referring to FIG. 4, the charging unit 200 according to the embodiment may include a capacitor 210 and a ground unit 220.

The charging unit 200 may be charged with charges and may generate and supply a voltage. The charging unit 200 may be connected to the switching unit. The charging unit 200 may supply or not supply the voltage to the power source of the communication unit according to whether the power source of the switching unit is turned on or off. The charging unit 200 may include the capacitor 210 (condenser) and the ground unit 220.

The charging unit 200 may be electrically connected to the switching unit. The charging unit 200 may include the charging unit 200 at the other end opposite to one end connected to the switching unit such that a potential difference occurs at the capacitor 210 to charge the charges. The voltage may be generated by charging the charging unit 200 with the charges.

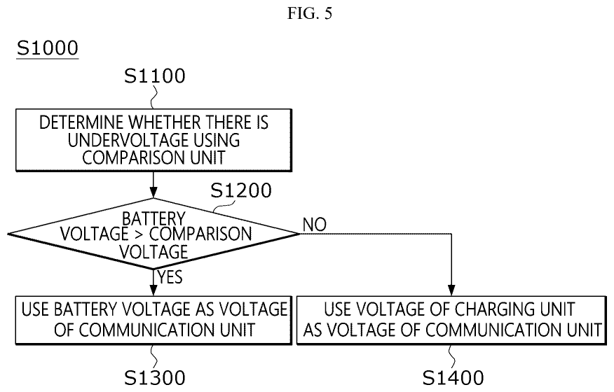

FIG. 5 is a flowchart illustrating an undervoltage protection method of the undervoltage protection circuit according to the embodiment.

Referring to FIG. 5, the undervoltage protection method S1000 may include determining, by the comparison unit, whether there is an undervoltage (S1100), determining whether a battery voltage is higher than a reference voltage (S1200), using the battery voltage as a voltage of the communication unit when the battery voltage is higher than the reference voltage (S1300), and using a voltage of the charging unit as the voltage of the communication unit when the battery voltage is lower than the reference voltage (S1400).

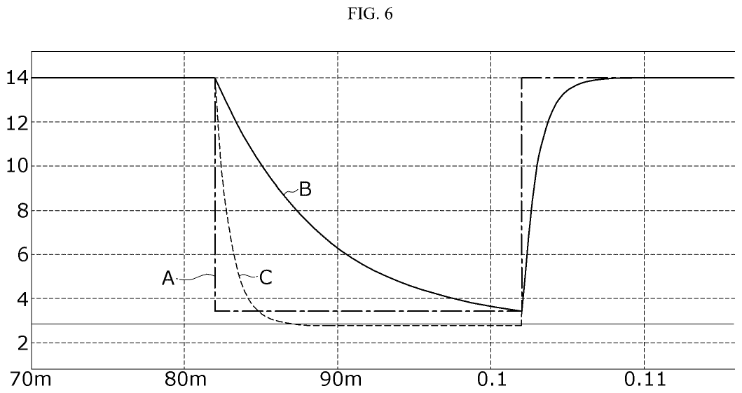

FIG. 6 is a graph showing a change in voltage according to the undervoltage protection circuit according to the embodiment.

Referring to FIG. 6, the graph shows the change in voltage over time.

Line A is a line showing a change of a battery voltage over time. When an undervoltage occurs at the battery voltage, a voltage significantly lowered from an existing voltage may be input. For example, the undervoltage may be maintained for 20 ms, and the existing voltage of the battery voltage may be lowered from 14.0 V to 3.5 V when the undervoltage occurs.

Line B is a line showing a voltage of the communication unit when the undervoltage protection circuit according to the embodiment is applied. When an undervoltage occurs at a battery voltage, the voltage of the communication unit is lowered. When the undervoltage protection circuit according to the embodiment is applied, a voltage of the charging unit supplements the voltage to increase a discharge time of the voltage when compared to the conventional case. Accordingly, while the undervoltage is maintained, a voltage is maintained higher than or equal to a limiting voltage. When the battery voltage is restored, the existing battery voltage is supplied to restore the voltage of the communication unit. Accordingly, when the undervoltage protection circuit according to the embodiment is applied,

Line C is a line showing a voltage of the communication unit when the undervoltage protection circuit according to the embodiment is not applied. When an undervoltage of a battery voltage occurs, a voltage of the communication unit is lowered. In the conventional case, since the undervoltage may not be determined when the undervoltage occurs, and the voltage may not be immediately supplemented, the voltage is discharged in a short time. Accordingly, there may be a period for which communication of the communication unit is impossible until the battery voltage is restored again.

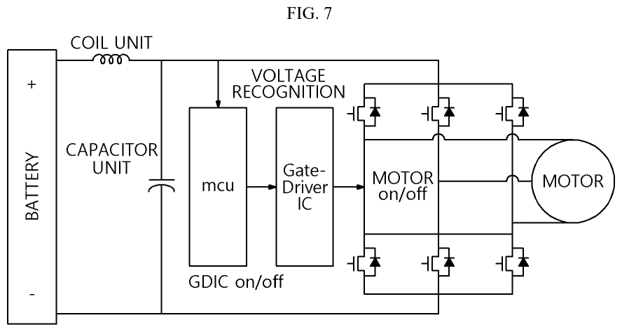

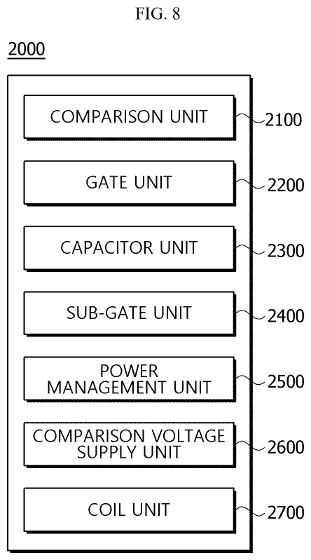

FIG. 7 is a circuit diagram illustrating a conventional motor control circuit.

The conventional motor control circuit may include a capacitor unit, a coil unit, a micro controller unit (MCU), and a gate driver IC (GDIC). In the conventional motor control circuit, a voltage of a battery may be transmitted to the MCU through the capacitor unit or a coil. In the conventional motor control circuit, a node at which an input voltage of the battery is input to the MCU may be behind a node at which the input voltage is transmitted through the capacitor unit or coil. The MCU may receive the input voltage of the battery, determine whether the corresponding input voltage is an undervoltage, and transmit a signal according to a determination result to the GDIC. As a result, the GDIC may turn a power source of the motor on or off according to the signal received from the MCU. The GDIC may turn the power source of the motor off when the input voltage of the battery is in an undervoltage state.

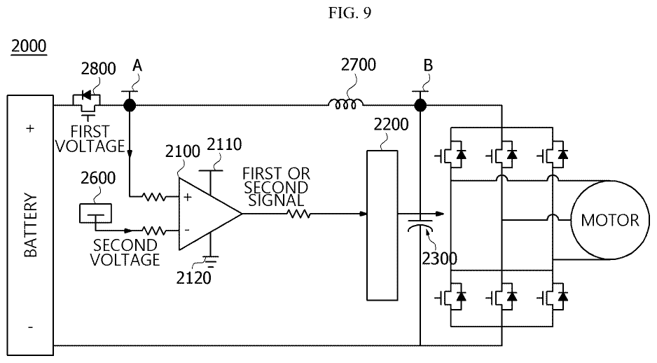

FIG. 8 is a block diagram illustrating a motor control circuit according to the embodiment.

Referring to FIG. 8, a motor control circuit 2000 according to the embodiment may include a comparison unit 2100, a gate unit 2200, a capacitor unit 2300, a sub-gate unit 2400, a power management unit 2500, a comparison voltage supply unit 2600, and a coil unit 2700.

FIG. 9 is a circuit diagram illustrating the motor control circuit according to the embodiment.

Referring to FIGS. 8 and 9, the motor control circuit 2000 according to the embodiment may include the comparison unit 2100 which compares magnitudes of a plurality of voltages, the gate unit 2200 which adjusts power to control the motor, and the capacitor unit 2300 which is charged with charges and supplies a current to a bridge circuit unit, the comparison unit 2100 may transmit a signal according to a result of comparing the magnitudes of the plurality of voltages to the gate unit 2200, the gate unit 2200 may adjust the power according to the result of comparing the magnitudes of the plurality of voltages, and an input node A at which the comparison unit 2100 receives a voltage may be disposed in front of a supply node B at which the capacitor unit receives a voltage.

The motor control circuit 2000 according to the embodiment may include the comparison unit 2100 which compares the magnitudes of the plurality of voltages.

The comparison unit 2100 may compare the magnitudes of the plurality of voltages. The comparison unit 2100 may be connected to a plurality of lines. The comparison unit 2100 may be connected to the plurality of lines and may receive voltages of the plurality of lines. The comparison unit 2100 may be connected to two lines and may compare magnitudes of two input voltages. The comparison unit 2100 may include positive terminals and negative terminals. The comparison unit 2100 may receive two voltages through the positive and negative terminals. The comparison unit 2100 may include a first signal unit 2110 and a second signal unit 2120. The comparison unit 2100 may be connected to the battery through the input node A and receive a first voltage through the input node A. The comparison unit 2100 may be electrically connected to the comparison voltage supply unit 2600 which provides a second voltage. The comparison unit 2100 may be electrically connected to the gate unit 2200.

The plurality of voltages of the motor control circuit 2000 according to the embodiment may include the first voltage and the second voltage, the first voltage may be an input voltage, and the second voltage may be a comparison voltage.

The comparison unit 2100 may receive the first voltage through the positive terminal and receive the second voltage through the negative terminal. The comparison unit 2100 may compare magnitudes of the first voltage and the second voltage and generate a first signal or second signal according to a result of the comparison. When the first voltage is higher, the comparison unit 2100 may generate the first signal. When the second voltage is higher, the comparison unit 2100 may generate the second signal.

The first voltage may be the input voltage. The input voltage may be a voltage input to the motor control circuit from an external battery. When an undervoltage of the input voltage occurs, operation of the motor may be stopped.

The second voltage may be the comparison voltage. The comparison voltage may be a voltage which is a reference of comparison with the first voltage in order to determine whether there is an undervoltage. A magnitude of the comparison voltage is not limited. For example, the magnitude of the comparison voltage may be 6 V. When the input voltage is 6 V or lower, the input voltage may be determined to be in an undervoltage state.

The comparison unit 2100 may compare magnitudes of the input voltage and the reference voltage. The comparison unit 2100 may be a comparator.

The comparison unit 2100 according to the embodiment may transmit a signal according to the result of comparing the magnitudes of the plurality of voltages to the gate unit 2200.

The comparison unit 2100 may compare the magnitudes of the plurality of voltages input to the positive terminals and the negative terminals, generate the signal according to the result of the comparison, and transmit the signal to the gate unit 2200. The comparison unit 2100 may compare the magnitudes of the first voltage and the second voltage, generate the signal according to the result of the comparison, and transmit the signal to the gate unit 2200. The comparison unit 2100 may compare the magnitudes of the input voltage and the comparison voltage.

Signals according to the embodiment may include the first signal and the second signal, the first signal may be a signal for allowing a current to flow, and the second signal may be a signal for blocking a current.

When the first voltage is higher than the second voltage, the comparison unit 2100 according to the embodiment may transmit the first signal to the gate unit 2200, and when the first voltage is lower than the second voltage, the comparison unit 2100 may transmit the second signal to the gate unit 2200.

The comparison unit 2100 may compare the magnitudes of the first voltage and the second voltage, generate the first signal or the second signal, and transmit the first signal or the second signal to the gate unit 2200.

The first signal may be the signal for allowing the current to flow. The first signal may be generated by the first signal unit 2110. The first signal may be a voltage generated by the first signal unit 2110. When the first voltage is higher than the second voltage, the comparison unit 2100 may transmit the first signal to the gate unit 2200. When the first voltage is higher than the second voltage, the gate unit 2200 may receive the first signal and allow the current to flow to the motor to continuously operate the motor.

The second signal may be the signal for blocking the current. The second signal may be generated by the second signal unit 120. The second signal may be a voltage generated by the second signal unit 2120. When the first voltage is lower than the second voltage, the comparison unit 2100 may transmit the second signal to the gate unit 2200. When the first voltage is lower than the second voltage, the gate unit 2200 may receive the second signal and block the current flowing to the motor to stop operation of the motor.

The comparison unit 2100 may include the first signal unit 2110 and the second signal unit 2120. The first signal unit 2110 and the second signal unit 2120 may be electrically connected to the comparison unit 2100.

The first signal unit 2110 may generate the first signal and transmit the first signal to the comparison unit 2100. The first signal unit 2110 may generate and transmit a predetermined voltage. When the first voltage is higher than the second voltage, the comparison unit 2100 may transmit the first signal of the first signal unit 2110 to the gate unit 2200.

The second signal unit 2120 may generate the second signal and transmit the second signal to the comparison unit 2100. The second signal unit 2120 may be a ground unit. When the first voltage is higher than the second voltage, the comparison unit 2100 may transmit the second signal of the second signal unit 2120 to the gate unit 2200.

The input node A at which the comparison unit 2100 according to the embodiment receives a voltage may be disposed in front of the supply node B at which the capacitor unit 2300 receives a voltage.

The comparison unit 2100 may receive the first voltage from the battery through the input node A. At the input node A, the voltage transmitted from the battery may be distributed to the comparison unit 2100. The capacitor unit 2300 may receive the first voltage from the battery through the supply node B. At the supply node B, the voltage transmitted from the battery may be distributed to the capacitor unit 2300. When the voltage of the battery is transmitted through the capacitor unit 2300, recognition of a change in voltage may be delayed.

The input node A may be disposed in front of the supply node B. A node at which the voltage of the battery is distributed to the comparison unit 2100 may be closer to the battery than a node at which the voltage of the battery is distributed to the capacitor unit 2300. When the comparison unit 2100 compares the magnitude of the first voltage and the magnitude of the second voltage, the first voltage may be distributed before being transmitted through the capacitor unit 2300. When the node at which the comparison unit 2100 recognizes the voltage is disposed in front of the capacitor unit 2300, the delayed recognition of the change in voltage due to the capacitor unit 2300 when the voltage of the battery dramatically changes may be prevented. Response for operation stop of the motor when an undervoltage occurs can be improved to be fast by preventing the delayed recognition of the change in voltage.

The motor control circuit 2000 according to the embodiment may include the gate unit 2200 which may adjust power to control the motor.

The gate unit 2200 of the motor control circuit 2000 according to the embodiment may adjust the power according to a result of comparing the magnitudes of the plurality of voltages.

When the gate unit 2200 of the motor control circuit 2000 according to the embodiment receives the first signal, the gate unit 2200 may turn a power source on and transmit a signal for operating the motor, and when the gate unit 2200 receives the second signal, the gate unit 2200 may turn the power source off and transmit a signal for stopping the operation of the motor.

The gate unit 2200 may adjust the power source to control operation of the motor according to whether the power source is turned on or off. As the gate unit 2200 receives the signal, the gate unit 2200 may turn the power source on or off. When the gate unit 2200 turns on the power source, the motor may operate. When the gate unit 2200 turns off the power source, the operation of the motor may be stopped. The gate unit 2200 may be electrically connected to the comparison unit 2100 or the motor. The gate unit 2200 may be disposed between the comparison unit 2100 and the motor. The gate unit 2200 may be a GDIC.

The gate unit 2200 may receive the first signal or the second signal from the comparison unit 2100. When the first voltage is higher than the second voltage, the gate unit 2200 may receive the first signal from the comparison unit 2100 and turn the power source on. When the power source of the gate unit 2200 is turned on, a signal for operating the motor may be transmitted to the bridge circuit unit. When the first voltage is lower than the second voltage, the gate unit 2200 may receive the second signal from the comparison unit 2100 and turn the power source off. When the power source of the gate unit 2200 is turned off, the signal for stopping the operation of the motor may be transmitted to the bridge circuit unit of the motor.

The motor control circuit 2000 according to the embodiment may include the capacitor unit 2300 which is charged with the charges and supplies the current to the bridge circuit unit.

The capacitor unit 2300 according to the embodiment may be disposed between the comparison unit 2100 and gate unit 2200 and the motor.

The capacitor unit 2300 may distribute a constant voltage to the bridge circuit unit which controls operation of the motor in both directions by being charged with the charges to generate the voltage and redistributing the voltage. The capacitor unit 2300 may be a DC link capacitor. The capacitor unit 2300 may be electrically connected to a battery voltage and the bridge circuit unit of the motor. The capacitor unit 2300 may be disposed between the battery and the bridge circuit unit of the motor. The capacitor unit 2300 may receive the first voltage from the battery through the supply node B. A node at which the capacitor unit 2300 receives the first voltage through the supply node B may be disposed behind a node at which the comparison unit 2100 receives the first voltage from the battery through the input node A. A resistor component of the capacitor unit 2300 may increase as a frequency of an AC current is lower to suppress a flow of the current.

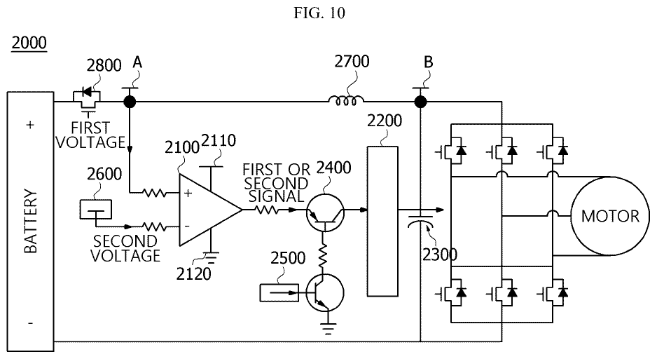

FIG. 10 is a circuit diagram illustrating a motor control circuit according to another embodiment.

Referring to FIGS. 8 and 10, a motor control circuit 2000 according to another embodiment may further include a sub-gate unit 2400 or power management unit 2500.

The motor control circuit 2000 according to the embodiment may further include the sub-gate unit 2400 which allows a current to flow when all input signals are first signals.

The sub-gate unit 2400 may allow the current to flow when all input signals are the first signals. The sub-gate unit 2400 may be electrically connected to a comparison unit 2100, the power management unit 2500, or a gate unit 2200. The sub-gate unit 2400 may allow the current to flow to the gate unit 2200 when all input signals are the first signals. The sub-gate unit 2400 may include a plurality of switches connected in series. The plurality of switches may receive the first signals or second signals. When all the plurality of switches receive the first signals and are connected, the sub-gate unit 2400 may allow the current to flow to the gate unit 2200.

The sub-gate unit 2400 according to the embodiment may be disposed between the comparison unit 2100 and the gate unit 2200.

The sub-gate unit 2400 may be disposed between and electrically connected to the comparison unit 2100 and the gate unit 2200. When the comparison unit 2100 receives the first signal, the sub-gate unit 2400 may allow the current to flow to the gate unit 2200, and when the comparison unit 2100 receives the second signal, the sub-gate unit 2400 may block the current which flows to the gate unit 2200.

When all input signals are the first signals, the sub-gate unit 2400 according to the embodiment may transmit the first signal to the gate unit 2200, and when any one signal of the input signals is the second signal, the sub-gate unit 2400 may block the current.

The sub-gate unit 2400 may be connected to the comparison unit 2100 and the power management unit 2500 and may receive the first signal or the second signal. When the sub-gate unit 2400 receives the first signals from both the comparison unit 2100 and the power management unit 2500, the sub-gate unit 2400 may allow the current to flow to the gate unit 2200 and transmit the first signal to the gate unit 2200. The sub-gate unit 2400 may transmit the first signal to the gate unit 2200 to turn a power source of the gate unit 2200 on and drive a motor. When the sub-gate unit 2400 receives the second signal from any one of the comparison unit 2100 and the power management unit 2500 or receives the second signals from the comparison unit 2100 and the power management unit 2500, the sub-gate unit 2400 may block a current which flows to the gate unit 2200. The sub-gate unit 2200 may block the current which flows to the gate unit 2200 to turn the power source of the gate unit 2200 off and stop operation of the motor.

The motor control circuit 2000 according to the embodiment may include the power management unit 2500 which converts and manages a current and distributes the current to the motor.

The power management unit 2500 according to the embodiment may be connected to the sub-gate unit 2400.

The power management unit 2500 may convert, distribute, or control a voltage input to the motor control circuit 2000. The power management unit 2500 may determine whether a voltage is an undervoltage according to an input voltage and control other elements accordingly. When a first voltage does not correspond to an undervoltage state, the power management unit 2500 may transmit the first signal to the sub-gate unit 2400. When the first voltage corresponds to the undervoltage state, the power management unit 2500 may transmit the second signal to the sub-gate unit 2400. The power management unit 2500 may be a power management IC (PMIC).

The motor control circuit 2000 according to the embodiment may include a comparison voltage supply unit 2600 for supplying a second voltage.

The comparison voltage supply unit 2600 may supply the second voltage. The comparison voltage supply unit 2600 may be electrically connected to the comparison unit 2100. The comparison voltage supply unit 2600 may supply the second voltage to the comparison unit 2100. The second voltage according to the embodiment may be 6 V. The comparison voltage supply unit 2600 may supply the voltage of 6 V to the comparison unit 2100.

The motor control circuit 2000 according to the embodiment may include a coil unit 2700 which generates a voltage according to a change in current.

The coil unit 2700 may induce the voltage proportional to an amount of a change in current. The coil unit 2700 may supply the induced voltage to a bridge circuit unit of the motor. The coil unit 2700 may be disposed between an input node A and a supply node B. When a current which flows in the coil unit 2700 is blocked, the voltage is generated. A resistor component of the coil unit 2700 may increase as a frequency of an AC current is lower to suppress a flow of the current. The coil unit 2700 may be an inductor. When the coil unit 2700 and the capacitor unit 2300 are used, only a current with a specific frequency may flow through the bridge circuit unit of the motor.

The motor control circuit 2000 according to the embodiment may include a reverse voltage prevention diode 2800.

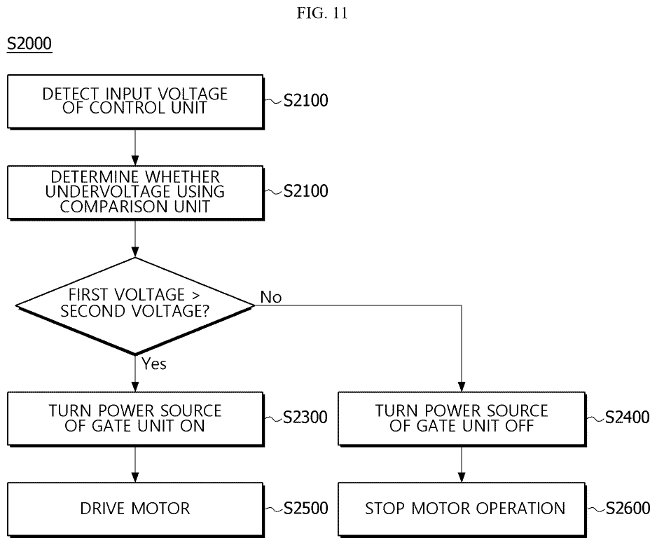

FIG. 11 is a flowchart illustrating a method of controlling a motor of the motor control circuit according to the embodiment.

Referring to FIG. 11, a method S2000 of controlling a motor of the motor control circuit according to the embodiment may include receiving and sensing an input voltage (S2100), determining, by the comparison unit, whether there is an undervoltage (S2200), turning the power source of the gate unit on when a first voltage is higher than a second voltage (S2300), turning the power source of the gate unit off when the first voltage is lower than the second voltage (S2400), driving the motor when the power source of the gate unit is turned on (S2500), and stopping operation of the motor when the power source of the gate unit is turned off (S2600).

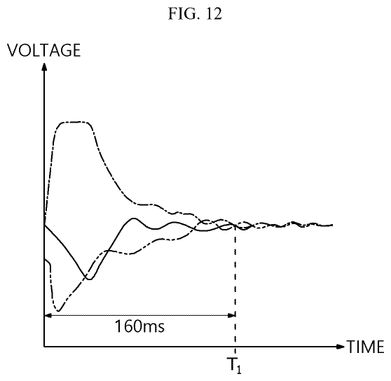

FIG. 12 is a graph showing a change in voltage according to the conventional motor control circuit.

Referring to FIG. 12, when the conventional motor control circuit is applied, and an undervoltage occurs, a time T1 to stop operation of a motor may be long. In the conventional motor control circuit, when the undervoltage occurs, the time T1 to stop the operation of the motor may be long. For example, when the undervoltage occurs in the conventional motor control circuit, the time T1 to block a voltage supplied to the motor and stop the operation of the voltage may be 160 ms. Response for operation stop of the motor of the conventional motor control circuit when an undervoltage occurs may be low.

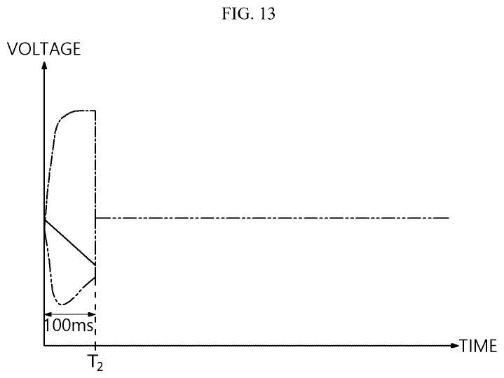

FIG. 13 is a graph showing a change in voltage according to the motor control circuit according to the embodiment.

Referring to FIG. 13, when the motor control circuit according to the embodiment is applied, and an undervoltage occurs, a time T2 required to stop operation of the motor may be short. The time T2 for the motor control circuit according to the embodiment to block a voltage supplied to the motor when the undervoltage occurs may be short. For example, the time T2 for the motor control circuit according to the embodiment to block the voltage supplied to the motor and stop the operation of the motor when the undervoltage occurs may be 100 ms. The response for operation stop of the motor control circuit according to the embodiment may be fast. The response for the operation stop of the motor of the motor control circuit according to the embodiment when the undervoltage occurs may be improved as much as 37.5% compared to the conventional case.

Referring to FIGS. 12 and 13, the motor control circuit according to the embodiment may reduce a time required to block a voltage supplied to the motor and stop operation of the motor when an undervoltage occurs by 37.5% when compared to the conventional motor control circuit. Accordingly, the motor control circuit according to the embodiment can improve response for operation of the motor according to a change in input voltage.

Hereinabove, while the present disclosure has been described with reference to embodiments, the embodiments are only exemplary and do not limit the present specification, and it will be understood by those skilled in the art that various changes and applications which are not illustrated above may be made without departing from the essential characteristics of the present embodiments. For example, components specifically described according to the embodiments may be modified. In addition, such differences relating to the modifications and applications should be understood to be included in the scope of the present specification defined by the appended claims.

1. An undervoltage protection circuit comprising:
a comparison unit that compares a battery voltage and a reference voltage;
a charging unit including a capacitor; and
a switching unit that allows any one of a voltage of the charging unit and the battery voltage to be supplied to a power source of a communication unit according to an output of the comparison unit.

2. The undervoltage protection circuit of claim 1, wherein, when the battery voltage is higher than the reference voltage, the switching unit allows the battery voltage to be supplied to the power source of the communication unit.

3. The undervoltage protection circuit of claim 1, wherein, when the battery voltage is lower than the reference voltage, the switching unit allows a voltage of the capacitor in the charging unit to be supplied to the power source of the communication unit.

4. The undervoltage protection circuit of claim 1, comprising a resistor disposed between the charging unit and the switching unit.

5. The undervoltage protection circuit of claim 1, wherein the reference voltage ranges from 3.3 V to 3.7 V.

6. The undervoltage protection circuit of claim 1, wherein, when the battery voltage is higher than the reference voltage, the comparison unit transmits a signal for turning a power source of the switching unit off.

7. The undervoltage protection circuit of claim 1, wherein, when the battery voltage is lower than the reference voltage, the comparison unit transmits a signal for turning a power source of the switching unit on.

8. The undervoltage protection circuit of claim 7, wherein, when the power source of the switching unit is turned on, the switching unit allows a current supplied by the charging unit to flow to the power source of the communication unit.

9. The undervoltage protection circuit of claim 1, wherein the switching unit is disposed between and electrically connected to the comparison unit, the charging unit, and the power source of the communication unit.

10. The undervoltage protection circuit of claim 1, comprising a voltage supply unit that generates the reference voltage.

11. The undervoltage protection circuit of claim 1, wherein the comparison unit compares the magnitudes of voltages input to positive and negative terminals and generates a first signal or second signal according to a result of the comparison.

12. The undervoltage protection circuit of claim 11, when a voltage input to the positive terminal is higher, the comparison unit generates the first signal, and when a voltage input to the negative terminal is higher, the comparison unit generates the second signal.

13. The undervoltage protection circuit of claim 12, wherein the comparison unit includes a first signal voltage supply unit and a second signal voltage supply unit; when the comparison unit generates the first signal, the comparison unit transmits a voltage of the first signal voltage supply unit to the switching unit, and when the comparison unit generates the second signal, the comparison unit transmits a voltage of the second signal voltage supply unit to the switching unit.

14. A motor control circuit comprising:
a comparison unit that compares magnitudes of a plurality of voltages;
a gate unit that adjusts power to control a motor; and
a capacitor unit that is charged with charges and supplies a current to a bridge circuit unit;
wherein the comparison unit transmits a signal according to a result of comparing the magnitudes of the plurality of voltages to the gate unit, the gate unit adjusts power according to the result of comparing the magnitudes of the plurality of voltages, and an input node at which the comparison unit receives the voltages is disposed in front of a supply node at which the capacitor unit receives the voltages.

15. The motor control circuit of claim 14, wherein the plurality of voltages includes a first voltage and a second voltage, the first voltage is an input voltage, and the second voltage is a comparison voltage.

16. The motor control circuit of claim 15, wherein the signal includes a first signal and a second signal, the first signal is a signal for allowing a current to flow, and the second signal is a signal for blocking the current.

17. The motor control circuit of claim 16, wherein the comparison unit transmits the first signal to the gate unit when the first voltage is higher than the second voltage and transmits the second signal to the gate unit when the first voltage is lower than the second voltage.

18. The motor control circuit of claim 17, wherein the gate unit transmits a signal for turning a power source on to drive a motor when the gate unit receives the first signal and transmit a signal for turning a power source off to stop operation of the motor when the gate unit receives the second signal.

19. The motor control circuit of claim 14, wherein the capacitor unit is disposed between the comparison unit and gate unit and the motor.

20. The motor control circuit of claim 16, comprising a sub-gate unit that allows a current to flow when each of all input signals is the first signal, and wherein the sub-gate unit is disposed between the comparison unit and the gate.
